(19) United States
(12) Patent Application Publication
(10) Pub. No.: US 2024/0154075 A1
(43) Pub. Date: May 9, 2024

(54) DISPLAY PANEL, DISPLAY APPARATUS, AND METHOD FOR MANUFACTURING DISPLAY PANEL

(71) Applicant: Shanghai Tianma Micro-Electronics Co., Ltd., Shanghai (CN)

(72) Inventors: Quanpeng YU, Shanghai (CN); Qijun YAO, Shanghai (CN); Yue XIE, Shanghai (CN)

(73) Assignee: Shanghai Tianma Micro-Electronics Co., Ltd., Shanghai (CN)

(21) Appl. No.: 18/403,738

(22) Filed: Jan. 4, 2024

(30) Foreign Application Priority Data
Sep. 28, 2023 (CN) 202311278606.7

(51) Int. Cl. H01L 33/54; H01L 25/16

(52) U.S. Cl. CPC H01L 33/54; H01L 25/167; H01L 2933/005

(57) ABSTRACT

A display panel, a display apparatus and a method for manufacturing a display panel are provided. The display panel includes: a base substrate; multiple light-emitting devices, where the light-emitting device includes a first semiconductor layer, a second semiconductor layer and a light-emitting layer located between the first and second semiconductor layers, and the second semiconductor layer is located on a side of the light-emitting layer away from the base substrate; a first package structure, located on the side of the base substrate, where the first package structure includes a first package part located between two adjacent light-emitting devices; and a second package structure, where at least part of the second package structure is located on a side of the light-emitting device away from the base substrate, and a resistivity of the first package structure is higher than that of the second package structure.

### CROSS-REFERENCE TO RELATED APPLICATIONS

This application claims priority to Chinese patent application No. 202311278606.7, titled “DISPLAY PANEL, DISPLAY APPARATUS, AND METHOD FOR MANUFACTURING DISPLAY PANEL”, filed Sep. 28, 2023, with the China National Intellectual Property Administration, which is incorporated herein by reference in its entirety.

### FIELD

The present disclosure relates to the field of display, and in particular to a display panel, a display apparatus and a method for manufacturing a display panel.

### BACKGROUND

Micro light emitting diodes (Micro-LED) are increasingly applied to light display panels. When the micro LED has a vertical structure, a cathode is fabricated on a side of the micro LED away from an array substrate. The cathode is usually patterned to reduce the blocking of light by the cathode, which is highly demanding on processing precision. As a result, this technique is complex and has high cost, and a yield of the product is also affected.

### SUMMARY

A display panel, a display apparatus and a method for manufacturing a display panel are provided in embodiments of the present disclosure, so that a fabrication technique is simplified, a demand for processing precision is reduced, a cost is reduced and a yield is improved.

In one embodiment, a display panel is provided, including: a base substrate; multiple light-emitting devices located on a side of the base substrate, where the light-emitting device includes a first semiconductor layer, a second semiconductor layer and a light-emitting layer located between the first semiconductor layer and the second semiconductor layer, where the second semiconductor layer is located on a side of the light-emitting layer away from the base substrate; a first package structure, located on the side of the base substrate, where the first package structure includes a first package part located between two adjacent light-emitting devices; a second package structure, where at least part of the second package structure is located on a side of the light-emitting device away from the base substrate; where a resistivity of the first package structure is σ1, a resistivity of the second package structure is σ2, and σ2<σ1.

In another embodiment, a display apparatus is provided, including a display panel, where the display panel includes: a base substrate; multiple light-emitting devices located on a side of the base substrate, where the light-emitting device includes a first semiconductor layer, a second semiconductor layer and a light-emitting layer located between the first semiconductor layer and the second semiconductor layer, where the second semiconductor layer is located on a side of the light-emitting layer away from the base substrate; a first package structure, located on the side of the base substrate, where the first package structure includes a first package part located between two adjacent light-emitting devices; a second package structure, where at least part of the second package structure is located on a side of the light-emitting device away from the base substrate; where a resistivity of the first package structure is σ1, a resistivity of the second package structure is σ2, and σ2<σ1.

In yet another embodiment, a method for manufacturing a display panel is provided, including: providing a base substrate;
providing a light-emitting device, where the light-emitting device includes a first semiconductor layer, a second semiconductor layer and a light-emitting layer located between the first semiconductor layer and the second semiconductor layer;
connecting the light-emitting device to the base substrate so that the second semiconductor layer is located on a side of the light-emitting layer away from the base substrate;
manufacturing a first package structure on a side of the base substrate facing the light-emitting device, where the first package structure includes a first package part located between two adjacent light-emitting devices, and a resistivity of the first package structure is σ1;
manufacturing a second package structure on a side of the first package structure away from the base substrate, where a resistivity of the second package structure is σ2, and σ2<σ1.

### BRIEF DESCRIPTION OF THE DRAWINGS

The drawings to be used in the description of the embodiments are described briefly as follows according to the embodiments of the present disclosure become clearer. It is apparent that the drawings in the following description only illustrate some embodiments of the present disclosure.

FIG. 1 is a schematic structural diagram of a display panel according to an embodiment of the present disclosure.

FIG. 2 is a schematic structural diagram of a display panel according to an embodiment of the present disclosure.

FIG. 3 is a schematic structural diagram of a display panel according to an embodiment of the present disclosure.

FIG. 4 is a schematic structural diagram of a display panel according to an embodiment of the present disclosure.

FIG. 5 is a top view of a display panel according to an embodiment of the present disclosure.

FIG. 6 is a sectional view of an A-A cross section of the display panel in FIG. 5 according to an embodiment of the present disclosure.

FIG. 7 is a schematic structural diagram of a display panel according to an embodiment of the present disclosure.

FIG. 8 is a schematic structural diagram of a display panel according to an embodiment of the present disclosure.

FIG. 9 is a schematic structural diagram of a display panel according to an embodiment of the present disclosure.

FIG. 10 is a schematic structural diagram of a display panel according to an embodiment of the present disclosure.

FIG. 11 is a schematic structural diagram of a display panel according to an embodiment of the present disclosure.

FIG. 12 is a sectional view of an A-A cross section of the display panel in FIG. 5 according to an embodiment of the present disclosure.

FIG. 13 is a sectional view of a B-B cross section of the display panel in FIG. 12 according to an embodiment of the present disclosure.

FIG. 14 is a schematic structural diagram of a display apparatus according to an embodiment of the present disclosure.

FIG. 15 is a flow chart of a method for manufacturing a display panel according to an embodiment of the present disclosure.

FIG. 16 is a flow chart of a method for manufacturing a display panel according to an embodiment of the present disclosure.

FIG. 17 is a flow chart of a method for manufacturing a display panel according to an embodiment of the present disclosure.

Legends in the drawings:
1. Base substrate;
2. Light-emitting device; 21. First semiconductor layer; 22. Light-emitting layer; 23. Second semiconductor layer; 24. First light-emitting device; 25. Second light-emitting device;
26. First electrode; 27. Reflective layer; 28. Second electrode;
3. First package structure; 31. First package part;
4. Second package structure; 41. First part; 42. Second part; 43. Third part; 44. Fourth part;
5. Array layer; 51. First connection part; 52. Thin film transistor;
6. Support structure;
7. Third package structure;
8. Touch layer; 81. Touch electrode layer; 82. Touch substrate;
9. Cover plate;
100. Display apparatus; 200. Display panel;
AA. Display area; NA. Non-display area; P1. First position; P2. Second position.

### DETAILED DESCRIPTION

The features and exemplary embodiments of the present disclosure are described in detail below. In the following detailed description, many specific details are provided to facilitate all-sided understanding of the present application. However, the present disclosure may be implemented without some of these specific details. The description of the exemplary embodiments is only intended to provide a better understanding of the present disclosure.

It should be noted that the embodiments of the present disclosure and features in the embodiments may be combined with each other in case of no conflict therebetween. Embodiments are described in detail below in conjunction with the drawings.

Relationship terms such as “first”, “second” and the like herein are merely for distinguishing an entity or operation from another and are not necessarily for indicating or implying an actual relationship or order between these entities or operations. Further, the terms “include”, “comprise” or any variant thereof are intended to encompass nonexclusive inclusion so that a process, method, article or device including a series of elements includes not only those elements but also other elements which have not been listed definitely or an element(s) inherent to the process, method, article or device. Without further limitations, an element preceded by the phrase “comprising a . . . ” does not exclude the presence of additional identical elements in the process, method, article or device including said element.

It should be understood that in description of the structure of the component, when a layer or an area is referred to as being “on” or “above” another layer or another area, it may be directly above the another layer or the another area, or other layers or areas may be included between the layer or the area and the another layer or the another area. And, if the component is flipped, the layer or the area may be located beneath or below the another layer or the another area.

In addition, the term “and/or” in the present disclosure simply describes an association relationship between associated objects, indicating presence of three kinds of relationships. For example, A and/or B indicates three cases: A alone, A and B together, and B alone. In addition, the character “I” in the present disclosure indicates that the associated objects before and after the character “I” are in an “or” relationship.

In embodiments of the present disclosure, “B corresponding to A” means that B is associated with A and B can be determined based on A. In addition, it should also be understood that determining B based on A does not mean determining B based on A alone, rather, B can also be determined based on A and/or other information.

It is found that when a micro light-emitting diode (Micro-LED) with a vertical structure is applied in a display panel, a semiconductor layer of the micro LED at one side is connected to a pixel circuit of an array substrate, and a semiconductor layer thereof at the other side is connected to a metal electrode to form a common electrode. In order to improve transmittance of light, the metal electrode is patterned to form arrayed openings. Special technique steps are performed in the patterning of the metal electrode, and high positioning accuracy is required. Therefore, a production technique of the entire display panel is more complex, the high demand on precision results in an increase in technique cost and processing difficulty, and correspondingly, a yield of the product is affected.

In view of the above, a display panel, a display apparatus and a method for manufacturing a display panel are provided in the present disclosure. The display panel includes a base substrate, a light-emitting device, a first package structure and a second package structure. A first package part of the first package structure is located between two adjacent light-emitting devices, and is at least configured to encapsulate a first semiconductor layer of the light-emitting device. The second package structure is set on a side of the first package structure away from the base substrate, and a resistivity of the second package structure is less than that of the first package structure, so that the second package structure can be configured to transmit a signal for the second semiconductor layer of the light-emitting device, for the light-emitting device to emit light. Because the metal electrode is replaced by the second package structure, the process of fabricating and patterning the metal electrode is saved, the structure of the display panel according to the embodiments of the present disclosure is simplified, and a method for manufacturing the display panel according to the embodiments of the present disclosure is simplified. As the second package structure can be fabricated integrally, a demand for precision is reduced through the method for manufacturing a display panel according to the embodiments of the present disclosure, to reduce the cost and improving the yield.

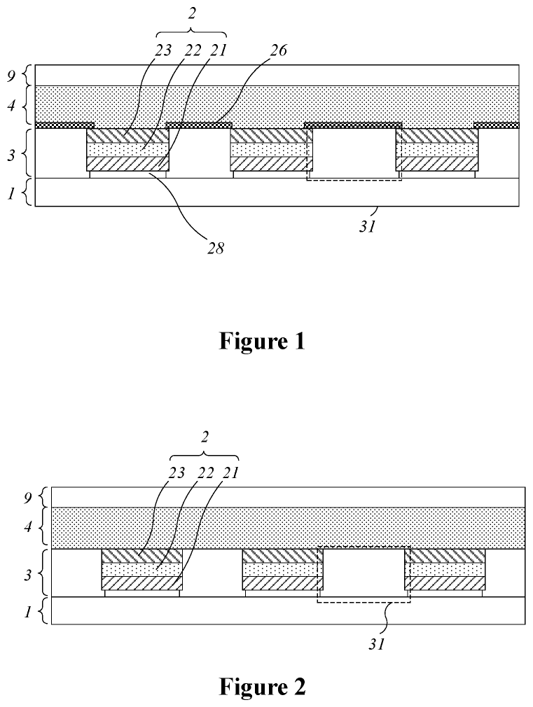

FIG. 1 is a schematic structural diagram of a display panel according to an embodiment of the present disclosure. FIG. 2 is another schematic structural diagram of a display panel according to an embodiment of the present disclosure.

Referring to FIG. 1 and FIG. 2, a display panel is provided according to an embodiment of the present disclosure, which includes: a base substrate 1; multiple light-emitting devices 2 located on a side of the base substrate 1, where the light-emitting device 2 includes a first semiconductor layer 21, a second semiconductor layer 23 and a light-emitting layer 22 located between the first semiconductor layer 21 and the second semiconductor layer 23, and the second semiconductor layer 23 is located on a side of the light-emitting layer 22 away from the base substrate 1; a first package structure 3, located on the side of the base substrate 1, where the first package structure 3 includes a first package part 31 located between two adjacent light-emitting devices 2; a second package structure 4, where at least part of the second package structure 4 is located on a side of the light-emitting device 2 away from the base substrate 1, where a resistivity of the first package structure 3 is σ1, a resistivity of the second package structure 4 is σ2, and σ2<σ1.

The base substrate 1 is fabricated by polymer materials such as glass, polyimide (PI), polycarbonate (PC), polyethersulfone (PES), polyethylene terephthalate (PET), polyethylene naphthalate (PEN), polyaryl compounds (PAR), or glass fiber reinforced plastics (FRP). The base substrate 1 may be transparent, translucent, or opaque.

The light-emitting device 2 is located on a side of the base substrate 1, and other film layers, such as an array layer, may also be set between the light-emitting device 2 and the base substrate 1. The display panel includes multiple light-emitting devices 2, and at least some of the multiple light-emitting devices 2 are arranged in an array. At least two of the multiple light-emitting devices 2 may each emit light with a different color. Each light-emitting device 2 includes a first semiconductor layer 21, a light emitting layer 22, and a second semiconductor layer 23. In the embodiment of the present disclosure, the light-emitting device 2 has a vertical structure, so the light-emitting layer 22 is located between the first semiconductor layer 21 and the second semiconductor layer 23. For illustrative purposes, in the embodiment of the present disclosure, the second semiconductor layer 23 is located on a side of the light-emitting functional layer away from the base substrate 1. The first semiconductor layer 21 may be electrically connected to the array layer, for example, the first semiconductor layer 21 is electrically connected to a pixel circuit of the array layer.

According to an embodiment of the present disclosure, the light-emitting device 2 may include a first electrode 26 and a second electrode 28, where the first electrode 26 is located on a side of the second semiconductor layer 23 away from the base substrate 1, and the second electrode 28 is located on a side of the first semiconductor layer 21 facing the base substrate 1.

The first package structure 3 is configured to encapsulate the second electrode 28 of the light-emitting device 2. Considering that the first semiconductor layer 21 of the light-emitting device 2 may be electrically connected to the array layer through the second electrode 28, the first package part 31 of the first package structure 3 is located between adjacent light-emitting devices 2, and encapsulates the first semiconductor layer 21 and the second electrode 28. In addition, there is a gap between two adjacent light-emitting devices 2, and the first package part 31 of the first package structure 3 may fill the gap to produce a flattening effect. For example, a side of the first package part 31 away from the base substrate 1 is arranged flush and coplanar with the side of the second semiconductor layer 23 away from the base substrate 1, to form a flat surface. When the first electrode 26 is fabricated, a material of the first electrode 26 is fabricated integrally and then patterned. As one part of the first electrode 26 is located on the side of the first package part 31 away from the base substrate 1 and another part thereof is located on the side of the second semiconductor layer 23 away from the base substrate 1, the difficulty of integrally fabricating the material of the first electrode 26 is reduced.

At least part of the second package structure 4 is located on a side of the light-emitting device 2 away from the base substrate 1, and the second package structure 4 may be in direct or indirect contact with the first package structure 3. As the resistivity σ1 of the first package structure 3 is greater than the resistivity 62 of the second package structure 4, the second package structure 4 is more conductive. The second package structure 4 may be electrically connected to the second semiconductor layer 23 of the light-emitting device 2 to transmit a signal for the light-emitting device 2 to emit light. Therefore, the fabrication process of the metal electrode is simplified, to simplify the fabrication process of the display panel according to the embodiment of the present disclosure. In addition, as the second package structure 4 can be fabricated integrally, a demand for precision is reduced, which reduces fabrication cost and improves yield, of the display panel according to the embodiment of the present disclosure. It should be noted that, the second package structure 4 may be in direct electrical contact with, or indirectly electrically connected to, the second semiconductor layer 23.

Furthermore, the resistivity σ1 of the first package structure 3 is greater than the resistivity 62 of the second package structure 4. As a whole, the first package structure 3 shows insulator properties, by which a risk of short circuit between the first semiconductor layer 21 and the second semiconductor layer 23 of the light-emitting device 2 is reduced, and the second package structure 4 shows conductor properties to transmit an electrical signal. For example, the first package structure 3 may be fabricated by photoresist, for example, an over-coating (OC) layer, and the second package structure 4 may be fabricated by adding a conductive material to optical clear adhesive (OCA), where the conductive material may be filamentary silver or a transfer type transparent conductive thin film (TCTF) material.

Considering that the second package structure 4 shows conductor properties, if the first electrode 26 is still present, the first electrode 26 and the second package structure 4 are configured to transmit an electrical signal together. Therefore, on one hand, the second package structure 4 is connected in parallel to the first electrode 26, to reduce an impedance of signal transmission. On the other hand, when the first electrode 26 is fabricated, the second package structure 4 can be fabricated integrally, to properly reduce the fabrication precision of the first electrode 26, and the yield of the display panel according to the embodiment of the present disclosure can meet requirements through the second package structure 4, to reduce the fabrication cost of the display panel according to the embodiment of the present disclosure. Considering that the second package structure 4 shows conductor properties, the first electrode 26 may be omitted, and the fabrication process of the first electrode 26 may be omitted accordingly, so that the method for manufacturing a display panel according to the embodiment of the present disclosure is simplified and the fabrication cost is reduced.

Further, referring to FIG. 2, the second semiconductor layer 23 is in direct contact with the second package structure 4. Thus, the second package structure 4 can more smoothly transmit signals to the light-emitting device 2. An internal resistance and thereby power consumption of the display panel according to the embodiment of the present disclosure are reduced. The metal electrode is omitted, so that the structure of the display panel according to the embodiment of the present disclosure is simplified, the cost thereof is reduced and the yield there of is improved.

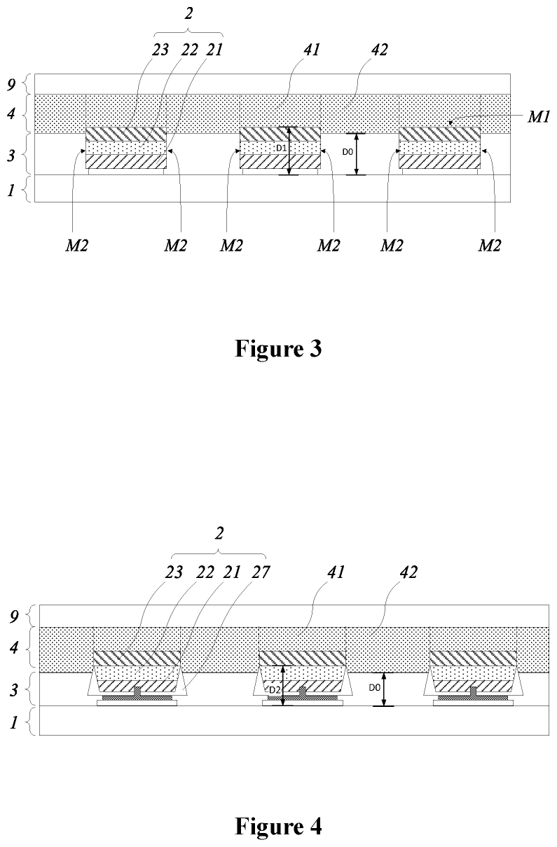

FIG. 3 is a schematic structural diagram of a display panel according to an embodiment of the present disclosure.

Further, referring to FIG. 3, the second package structure 4 includes a first part 41 and a second part 42. Along a direction perpendicular to a plane of base substrate 1, the first part 41 overlaps with the light-emitting device 2, and the second part 42 does not overlap with the light-emitting device 2. Along the direction perpendicular to the plane of base substrate 1, a distance from a surface of the second semiconductor layer 23 away from the base substrate 1 to the base substrate 1 is D1, and a distance from a surface of the second part 42 facing the base substrate 1 to the base substrate 1 is D0, where D0<D1.

Along a thickness-wise direction of base substrate 1, the first part 41 of the second package structure 4 overlaps with the light-emitting device 2, and the second part 42 is completely staggered with the light-emitting device 2. The light-emitting device 2 has a first surface M1 and a first side surface M2. The first surface M1 is located on a side of the second semiconductor layer 23 away from the base substrate 1. The first side surface M2 is a closed side surface of the light-emitting device 2. The first side surface M2 extends along a thickness-wise direction of the display panel according to the embodiment of the present disclosure to form a first space on a side of the first surface M1 away from the base substrate 1. The first part 41 is located in the first space, and may be in contact with the first surface M1. For two adjacent light-emitting devices 2, a second space is formed by extending an area between two first side surfaces M2 of the two light-emitting devices 2 along the thickness-wise direction of the display panel according to the embodiment of the present disclosure, and the second part 42 is located in the second space. It should be noted that, the first surface M1 of the light-emitting device 2 is extended to form a first reference surface. The second space is divided into a first subspace and a second subspace by the first reference surface. The first subspace is located on a side of the first reference surface facing the base substrate 1, and the second subspace is located on a side of the first reference surface away from the base substrate 1. At least part of the second part 42 may be located in the first subspace, and at least part of the second part 42 may be located in the second subspace.

The first part 41 is in contact connection with a side of the light-emitting device 2 away from the base substrate 1. The distance D1 from the surface of the second semiconductor layer 23 away from the base substrate 1 to the base substrate 1 is greater than the distance D0 from the surface of the second part 42 facing the base substrate 1 to the base substrate 1, so that part of the second part 42 is located between two adjacent light-emitting devices 2. That is, the second part 42 is in contact connection with a side surface of the second semiconductor layer 23, so that a contact area between the second part 42 and the second semiconductor layer 23 is increased, to reduce a contact resistance between the second part 42 and the second semiconductor layer 23, improving the conductivity and reducing the power consumption of the display panel according to the embodiment of the present disclosure.

FIG. 4 is a schematic structural diagram of a display panel according to an embodiment of the present disclosure.

Further, referring to FIG. 4, along the direction perpendicular to the plane of base substrate 1, a distance from a surface of the second semiconductor layer 23 facing the base substrate 1 to the base substrate 1 is D2, where D0<D2.

The light-emitting device 2 also includes a reflective layer 27, where one part of the reflective layer 27 is located on the side of the first semiconductor layer 21 facing the base substrate 1, and another part of the reflective layer 27 surrounds the first semiconductor layer 21 and the light-emitting layer 22, and extends along the thickness-wise direction of the display panel to the surface of the second semiconductor layer facing the base substrate 1, so that light emitted by the light-emitting layer 22 towards the base substrate 1 can also exit the light-emitting device 2 in a direction away from the base substrate 1. The distance D0 from the surface of the second part 42 facing the base substrate 1 to the base substrate 1 is less than or equal to the distance D2 from the surface of the second semiconductor layer 23 facing the base substrate 1 to the base substrate 1. That is, a part of the second part 42 may be in contact with the reflective layer 27 surrounding the light-emitting layer 22 and in the same layer as the light-emitting layer 22, while the second part 42 should not be in contact with, or in the same layer as, the first semiconductor layer 21. That is, an end surface of the second part 42 facing the base substrate 1 may be located between an end of the reflective layer 27 away from the base substrate 1 and an end of the first semiconductor layer 21 away from the base substrate 1. Considering that the second package structure 4 has a conductive ability, the second part 42 is not in contact with, or in the same layer as, the first semiconductor layer 21 of the light-emitting device 2, to reduce impact on the light-emitting device 2 caused by breakdown or short circuit of the second part 42.

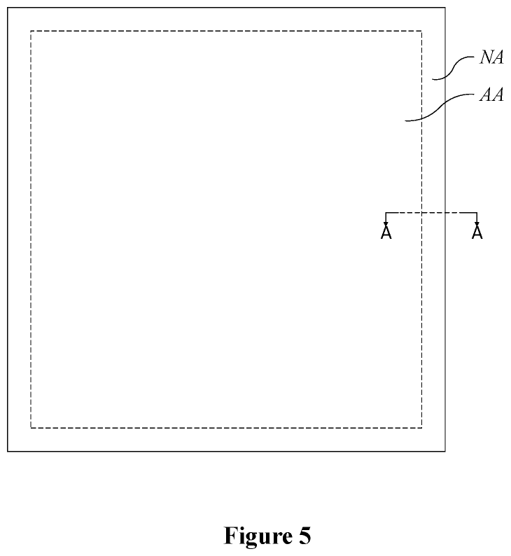

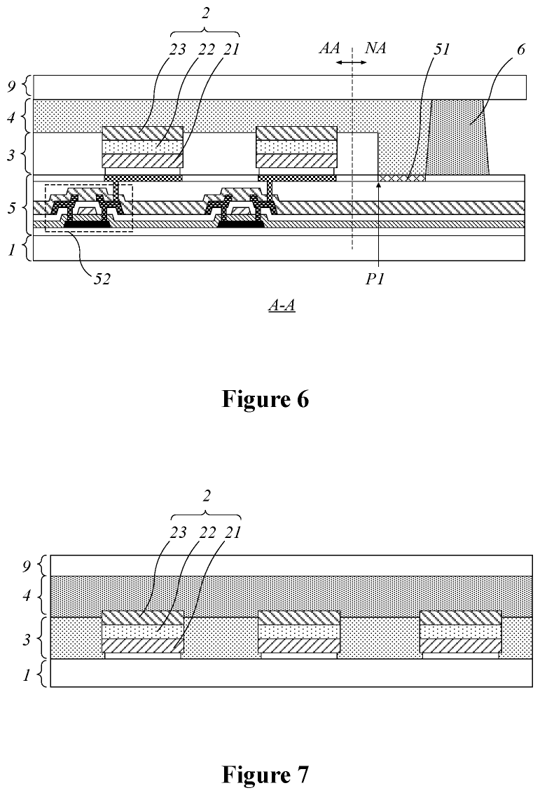

FIG. 5 is a top view of a display panel according to an embodiment of the present disclosure. FIG. 6 is a sectional view of an A-A cross section of the display panel in FIG. 5 according to an embodiment of the present disclosure.

Further, referring to FIG. 5 and FIG. 6, the display panel according to an embodiment of the present disclosure further includes: a display area AA and a non-display area NA, where at least part of the non-display area NA surrounds the display area AA; a support structure 6 located in the non-display area NA, where the support structure 6 at least partly surrounds the second package structure 4; an array layer 5 located on a side of the base substrate 1, where the light-emitting device 2 is located on a side of the array layer 5 away from the base substrate 1, the array layer 5 includes a first connection part 51 located in the non-display area NA, the first connection part 51 is located on a side of support structure 6 closer to the display area AA, and at least part of the second package structure 4 is in contact connection with the first connection part 51.

The light-emitting device 2 is located in the display area AA, and the non-display area NA partly surrounds the display area AA. The support structure 6 is located in the non-display area NA and is configured to support a cover plate of the display panel according to the embodiment of the present disclosure. The support structure 6 partly surrounds the second package structure 4. In the non-display area NA, part of the second package structure 4 is located on a side of the first package structure 3 away from the display area AA.

The array layer 5 is located between the base substrate 1 and the light-emitting device 2. The array layer 5 includes multiple thin film transistors (TFT) and a pixel circuit composed of thin film transistors. The structural description in the embodiment of the present disclosure is formulated by taking a top-gate thin film transistor for example. The array layer 5 includes an active layer for forming a thin film transistor, where the active layer includes a source region and a drain region formed by doping N-type impurity ions or P-type impurity ions, and a channel region between the source region and the drain region; a gate insulation layer located on the active layer; a gate of the thin film transistor located on the gate insulation layer. A source and a drain are electrically connected (or coupled) to the source region and drain region through contact holes respectively. The array layer 5 further includes a first connection part 51 located in the non-display area NA. The first connection part 51 is in contact connection with the second package structure 4 in the non-display area NA, the second package structure 4 is in contact connection with the second semiconductor layer 23 of the light-emitting device 2, and the pixel circuit is electrically connected to the first semiconductor layer 21 of the light-emitting device 2, so that the array layer 5 can control the light-emitting device 2.

Further, referring to FIG. 6, in the non-display area NA, the first package structure 3 ends at a first position P1, and the first position P1 is located on a side of the first connection part 51 closer to the display area AA.

Since the first package structure 3 ends at the first position P1, the second package structure 4 may be extended towards the base substrate 1 on a side of the first position P1 away from the display area AA, and in contact connection with the first connection part 51. In this case, the support structure 6 may be arranged on a side of this part of the second package structure 4, extending towards the base substrate 1, away from the display area AA.

Further, the support structure 6 is made of the same material as the first package structure 3.

Considering that the first package structure 3 shows insulator properties as a whole, the support structure 6 also shows insulator properties, so that the entry of external static electricity into the display panel according to the embodiment of the present disclosure is reduced. In addition, the first package structure 3 and the support structure 6 may be both fabricated by an organic material, so that the entry of external water vapor into the display panel according to the embodiment of the present disclosure is reduced.

FIG. 7 is a schematic structural diagram of a display panel according to an embodiment of the present disclosure.

Further, referring FIG. 7, the first package structure 3 includes a first conductive material, where a volume concentration of the first conductive material in the first package structure 3 is P1. The second package structure 4 includes a second conductive material, and a volume concentration of the second conductive material in the second package structure 4 is P2, where P1<P2.

According to the embodiment of the present disclosure, the first package structure 3 shows insulator properties as a whole, though the first package structure 3 contains a small amount of first conductive material. The volume concentration P1 of the first conductive material in the first package structure 3 is very small, so the first package structure 3 still shows insulator properties. The second package structure 4 shows conductor properties as a whole, and contains an amount of second conductive material, so that the volume concentration P2 of the second conductive material in the second package structure 4 is significantly greater than the volume concentration P1 of the first conductive material in the first package structure 3; therefore the second package structure 4 shows conductor properties. For example, the first conductive material may be filamentary silver or a transfer type transparent conductive thin film (TCTF) material, the second conductive material may also be filamentary silver wire or a transfer type transparent conductive thin film (TCTF) material, and the first conductive material may be the same as, or different from, the second conductive material.

Further, referring to FIG. 7, the first package structure 3 and the second package structure 4 both include a first insulating material. The first conductive material is the same as the second conductive material.

When the first package structure 3 and the second package structure 4 are fabricated, both the first package structure 3 and the second package structure 4 may be formed by a mixture of the first insulating material and the first conductive material. The first insulating material is mixed with only a very small amount of the first conductive material, to fabricate the first package structure 3. The first insulating material is distinctly mixed with the first conductive material, to fabricate the second package structure 4. As the first package structure 3 and the second package structure 4 are made of the same materials but with different ratios therebetween, the fabrication technique of the first package structure 3 and the second package structure 4 is simplified, to reduce the fabrication cost of the display panel according to the embodiment of the present disclosure.

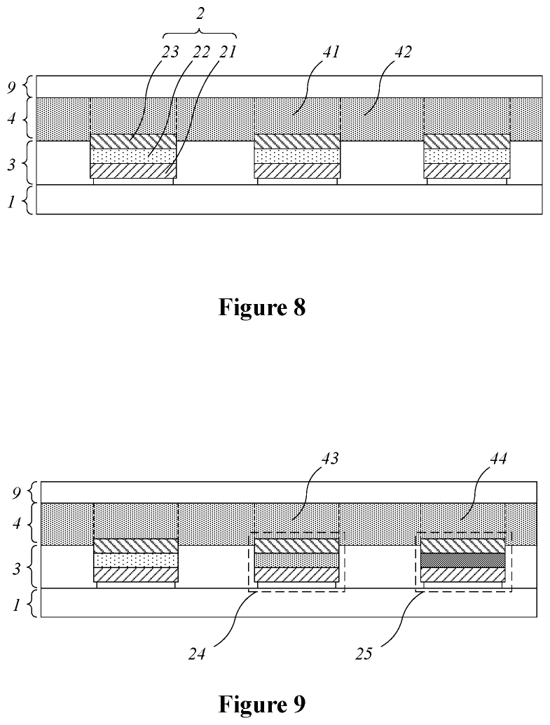

FIG. 8 is a schematic structural diagram of a display panel according to an embodiment of the present disclosure.

Further, referring to FIG. 8, the second package structure 4 includes a first part 41 and a second part 42. Along the direction perpendicular to the plane of the base substrate 1, the first part 41 overlaps with the light-emitting device 2 and the second part 42 does not overlap with the light-emitting device 2. A volume concentration of the first conductive material in the first part 41 is P21, and a volume concentration of the first conductive material in the second part 42 is P22, where P21≤P22.

According to the embodiment of the present disclosure, the volume concentration P21 of the first conductive material in the first part 41 is less than or equal to the volume concentration P22 of the first conductive material in the second part 42. When the second package structure 4 is fabricated, the volume concentration P21 of the first conductive material in the first part 41 may be appropriately reduced, to reduce influence of the first conductive material on a light transmittance of the first part 41, considering that the first part 41 is located on a light-emitting side of the light-emitting device 2. In addition, the volume concentration P22 of the first conductive material in the second part 42 is appropriately increased, so that the second package structure 4 has a good electrical conductivity.

FIG. 9 is a schematic structural diagram of a display panel according to an embodiment of the present disclosure.

Further, referring to FIG. 9, the light-emitting device 2 includes a first light-emitting device 24 and a second light-emitting device 25. A wavelength of light emitted by the first light-emitting device 24 is greater than a wavelength of light emitted by the second light-emitting device 25. The second package structure 4 includes a third part 43 and a fourth part 44. In the plane of the base substrate 1, an orthographic projection of the first light-emitting device 24 is located within an orthographic projection of the third part 43, and an orthographic projection of the second light-emitting device 25 is located within an orthographic projection of the fourth part 44. A volume concentration of the first conductive material in the third part 43 is P23, and a volume concentration of the first conductive material in the fourth part 44 is P24, where P23≥P24.

Since the volume concentration P23 of the first conductive material in the third part 43 is greater than or equal to the volume concentration P24 of the first conductive material in the fourth part 44, a light transmittance of the fourth part 44 is lower than that of the third part 43. The first light-emitting device 24 and the second light-emitting device 25 emit light of different colors. For example, the first light-emitting device 24 emits red light, and the second light-emitting device 25 emits blue light. As human eyes are less sensitive to blue light, by improving the light transmittance of the fourth part 44, the brightness of blue light sensed by the human eyes can be close to that of red light sensed by the human eyes.

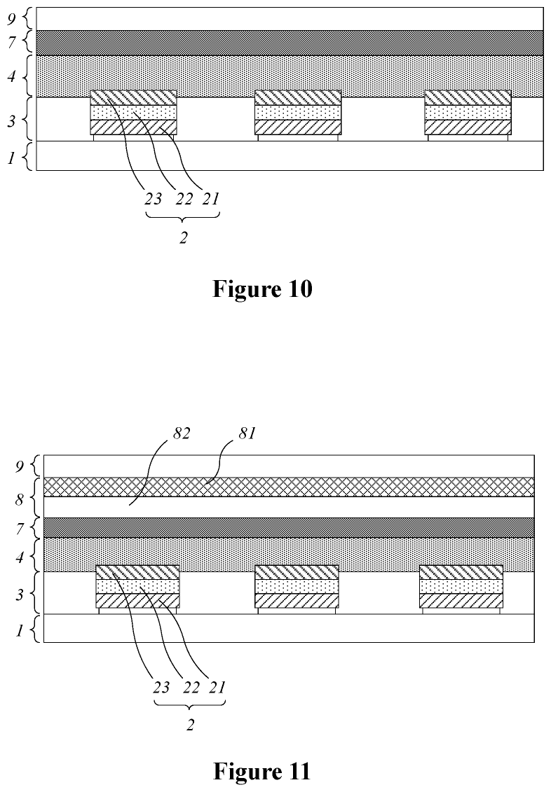

FIG. 10 is a schematic structural diagram of a display panel according to an embodiment of the present disclosure.

Further, referring to FIG. 10, the display panel according to an embodiment of the present disclosure further includes a third package structure 7. At least part of the third package structure 7 is located on the side of the second package structure 4 away from the base substrate 1. A resistivity of the third package structure 7 is σ3, and σ3<σ2.

The third package structure 7 is further provided on the side of the second package structure 4 away from the base substrate 1. The resistivity 63 of the third package structure 7 is less than the resistivity 62 of the second package structure 4, that is, the conductivity of the third package structure 7 is higher than that of the second package structure 4. The second package structure 4 and the third package structure 7 jointly transmit a signal to the light-emitting device 2, so that an internal resistance of the display panel according to the embodiment of the present disclosure is further reduced, to reduce the power consumption. For example, the third package structure 7 may be a transparent indium tin oxide (ITO) layer. The third package structure 7 may also be obtained by adding the first conductive material to the first insulating material.

FIG. 11 is a schematic structural diagram of a display panel according to an embodiment of the present disclosure.

Further, referring to FIG. 11, the display panel according to an embodiment of the present disclosure further includes a touch layer 8. The touch layer 8 includes a touch electrode layer 81 and a touch substrate 82, the touch substrate 82 is located on the side of the second package structure 4 away from the base substrate 1, and the touch electrode layer 81 is located on a side of the touch substrate 82 away from the base substrate 1. The third package structure 7 is located on a side of the touch substrate 82 away from the touch electrode layer 81, and in contact connection with the touch substrate 82.

The touch layer 8 is used to implement a touch function of the display panel according to the embodiment of the present disclosure. The touch electrode layer 81 is set on the side of the touch substrate 82 away from the base substrate 1, and the touch substrate 82 faces the third package structure 7. When the display panel according to the embodiment of the present disclosure is fabricated, after finishing fabricating the second package structure 4, the touch layer 8 may be fabricated first, the third package structure 7 is fabricated on a side of the touch substrate 82 away from the touch electrode layer 81, and then the touch layer 8 with the third package structure 7 is connected to the second package structure 4. For example, the third package structure 7 may be a transparent indium tin oxide (ITO) layer. Considering that both the second package structure 4 and the third package structure 7 can be fabricated integrally, a demand for positioning accuracy is low when the second package structure 4 is connected to the third package structure 7, so that the fabrication cost of the display panel according to the embodiment of the present disclosure is reduced and the yield thereof is improved.

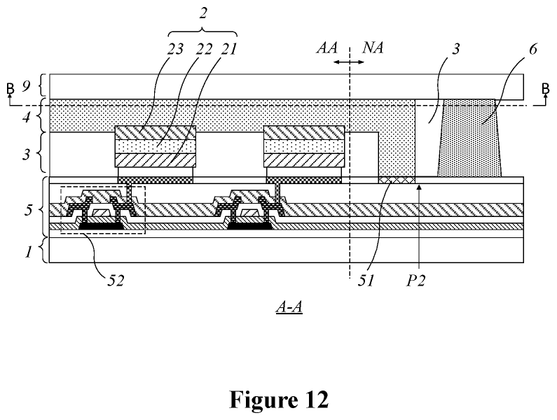

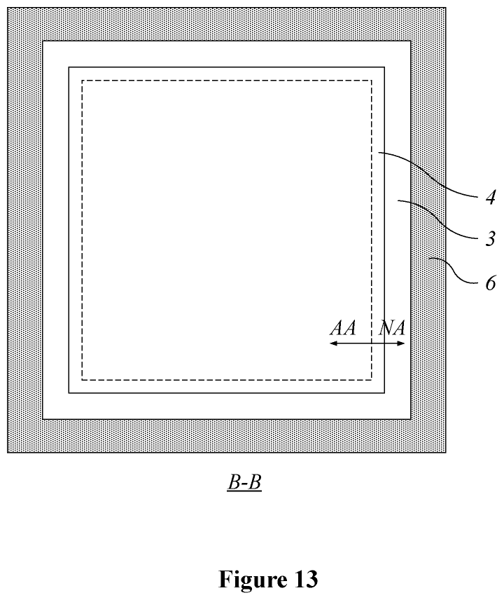

FIG. 12 is a sectional view of an A-A cross section of the display panel in FIG. 5 according to an embodiment of the present disclosure. FIG. 13 is a sectional view of a B-B cross section of the display panel in FIG. 12 according to an embodiment of the present disclosure.

Further, referring to FIG. 12 and FIG. 13, the display panel in an embodiment of the present disclosure further includes: a display area AA and a non-display area NA, where at least part of the non-display area NA surrounds the display area AA; a support structure 6 located in the non-display area NA, where the support structure 6 at least partly surrounds the first package structure 3; an array layer 5 located on a side of the base substrate 1, where the light-emitting device 2 is located on a side of the array layer 5 away from the base substrate 1, the array layer 5 includes a first connection part 51 located in the non-display area NA, and the first connection part 51 is located on a side of the support structure 6 closer to the display area AA.

The light-emitting device 2 is located in the display area AA, and the non-display area NA partly surrounds the display area AA. The support structure 6 is located in the non-display area NA and is configured to support a cover plate of the display panel according to the embodiment of the present disclosure. The support structure 6 partly surrounds the first package structure 3. In the non-display area NA, part of the first package structure 3 is located on the side of the first package structure 4 away from the display area AA.

The array layer 5 is located between the base substrate 1 and the light-emitting device 2. The array layer 5 includes multiple thin film transistors (TFT) and a pixel circuit composed of the thin film transistors. The structural description in the embodiment of the present disclosure is formulated by taking a top-gate thin film transistor for example. The array layer 5 includes an active layer for forming a thin film transistor, where the active layer includes a source region and a drain region formed by doping N-type impurity ions or P-type impurity ions, and a channel region between the source region and the drain region; a gate insulation layer located on the active layer; a gate of the thin film transistor located on the gate insulation layer. A source and a drain are electrically connected (or coupled) to the source region and the drain region through contact holes respectively. The array layer 5 also includes a first connection part 51 located in the non-display area NA. The first connection part 51 is in contact connection with the second package structure 4 in the non-display area NA, the second package structure 4 is in contact connection with the second semiconductor layer 23 of the light-emitting device 2, and the pixel circuit is electrically connected to the first semiconductor layer 21 of the light-emitting device 2, so that the array layer 5 can control the light-emitting device 2. At the first connection part 51, the first package layer may be provided with a hole so that a part of the second package structure 4 can pass through the hole and be in contact connection with the first connection part 51.

Further, referring to FIG. 12 and FIG. 13, in the non-display area NA, the second package structure 4 ends at a second position P2, and the second position P2 is located on a side of the first connection part 51 away from the display area AA.

Since the second package structure 4 ends at the second position P2, the first package structure 3 can extend away from the base substrate 1 on a side of the second position P2 away from the display area AA, to be flush with the side of the second package structure 4 away from the base substrate 1. In this case, the support structure 6 may be arranged on a side of this part of the first package structure 3, extending away from the base substrate 1, away from the display area AA.

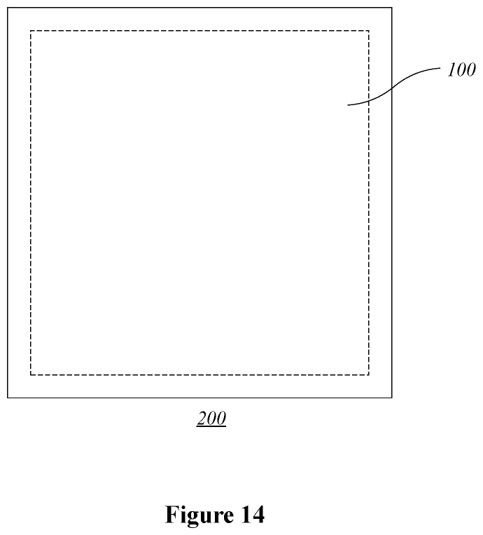

FIG. 14 is a schematic structural diagram of a display apparatus according to an embodiment of the present disclosure.

Referring to FIG. 14, a display apparatus 100 is further provided according to an embodiment of the present disclosure, which includes the display panel 200 according to the aforementioned embodiments of the present disclosure. The display apparatus 100 according to the embodiment of the present disclosure may be any product or component having a display function such as a mobile phone, a tablet computer, a television, a monitor, a laptop, a digital photo frame, a navigator and so on.

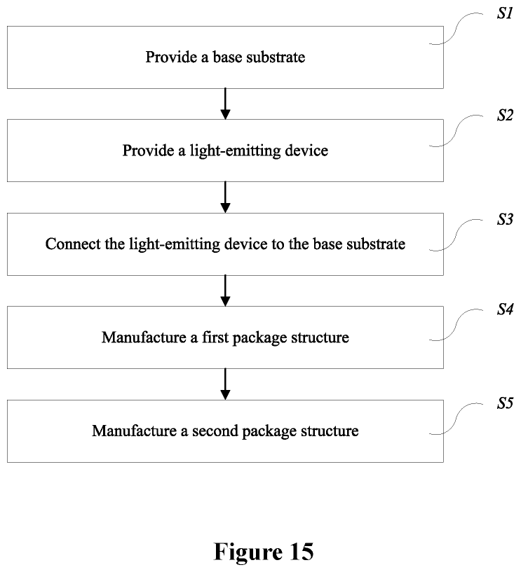

FIG. 15 is a flow chart of a method for manufacturing a display panel according to an embodiment of the present disclosure.

Referring to FIG. 15, a method for manufacturing a display panel is provided according to an embodiment of the present disclosure, which can be used to fabricate the display panel according to the aforementioned embodiments of the present disclosure.

The method for manufacturing a display panel according to an embodiment of the present disclosure includes the following steps S1 to S5.

In step S1, a base substrate is provided.

A finished product of the base substrate 1 may be directly obtained, or the substrate 1 may alternatively be fabricated.

In step S2, a light-emitting device 2 is provided.

Similarly, a finished product of the light-emitting device 2 may be directly obtained, or the light-emitting device 2 may alternatively be fabricated. According to an embodiment of the present disclosure, the light-emitting device 2 includes a first semiconductor layer 21, a second semiconductor layer 23 and a light-emitting layer 22 located between the first semiconductor layer 21 and the second semiconductor layer 23. The light-emitting device 2 has a vertical structure, so that the light-emitting layer 22 is located between the first semiconductor layer 21 and the second semiconductor layer 23.

In step S3, the light-emitting device 2 is connected to the base substrate 1.

After the light-emitting device 2 is connected to the base substrate 1, the second semiconductor layer 23 of the light-emitting device 2 is located on a side of the light-emitting layer 22 away from the base substrate 1. Other film layers, such as an array layer 5, may also be set between the light-emitting device 2 and the base substrate 1.

In step S4, a first package structure 3 is manufactured.

The first package structure 3 is manufactured on a side of the base substrate 1 facing the light-emitting device 2, where the first package structure 3 includes a first package part 31 located between two adjacent light-emitting devices 2, so that a joint between the light-emitting device 2 and the base substrate 1 can be encapsulated by the first package structure 3. A resistivity of the first package structure σ1 is high, and therefore the first package structure 3 shows insulator properties.

In step S5, a second package structure 4 is manufactured.

The second package structure 4 is manufactured on a side of the first package structure 3 away from the base substrate 1, so that the second package structure 4 covers at least part of the first package structure 3. A resistivity 62 of the second package structure 4 is less than the resistivity σ1 of the first package structure 3, and the second package structure 4 shows conductor properties and is configured for transmitting a signal to the second semiconductor layer 23 of the light-emitting device 2, to control the light-emitting device 2.

Further, in the step S5, manufacturing the second package structure 4 on the side of the first package structure 3 away from the base substrate 1 includes: manufacturing a first insulating material on the side of the first package structure 3 away from the base substrate 1, and adding a second conductive material to the first insulating material. By adding a second conductive material to the first insulating material, the second package structure 4 has conductivity.

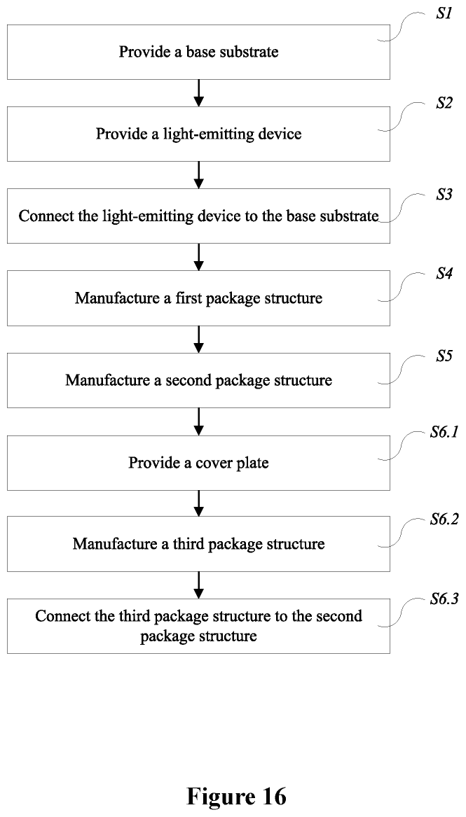

FIG. 16 is a flow chart of a method for manufacturing a display panel according to an embodiment of the present disclosure.

Further, referring to FIG. 16, the method for manufacturing a display panel according to an embodiment of the present disclosure further includes the following steps S6.1 to S6.3.

In step S6.1, a cover plate is provided.

A finished product of the cover plate may be directly obtained, or the cover plate may alternatively be fabricated, where the cover plate is used to protect the display panel.

In step S6.2, a third package structure 7 is manufactured.

The third package structure 7 is manufactured on a side of the cover plate. For example, a transparent indium tin oxide (ITO) layer may be manufactured directly on the side of the cover plate; or a first insulating material may be manufactured on the side of the cover plate first, and then a conductive material is added to the first insulating material.

In step S6.3, the third package structure 7 is connected to the second package structure 4.

A side of the third package structure 7 away from the cover plate is connected to a side of the second package structure 4 away from the base substrate 1. Since both the second package structure 4 and the third package structure 7 can be fabricated integrally, when the second package structure 4 is connected to the third package structure 7, the demand of the positioning accuracy is low, so that the fabrication cost of the display panel according to the embodiment of the present disclosure is reduced and the yield thereof is improved.

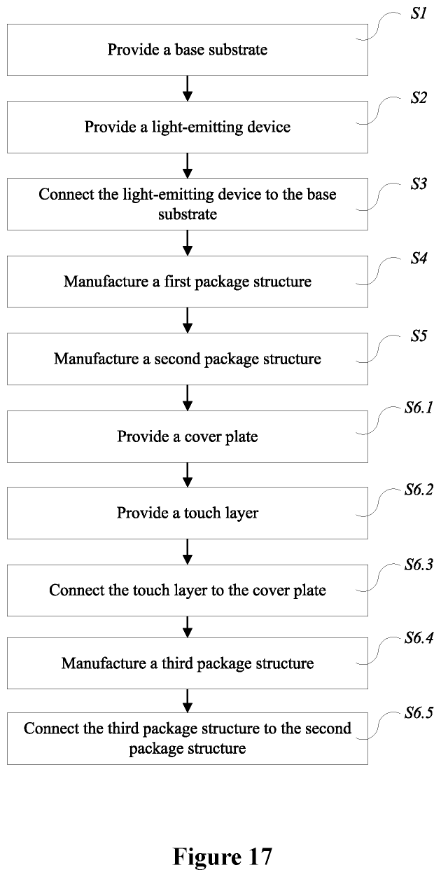

FIG. 17 is a flow chart of a method for manufacturing a display panel according to an embodiment of the present disclosure.

Further, referring to FIG. 17, the method for manufacturing a display panel according to an embodiment of the present disclosure further includes the following steps S6.1 to S6.5.

In step S6.1, a cover plate is provided.

A finished product of the cover plate may be directly obtained, or the cover plate may alternatively be fabricated, where the cover plate is used to protect the display panel.

In step S6.2, a touch layer 8 is provided.

A finished product of the touch layer 8 may be directly obtained, or the touch layer 8 may alternatively be fabricated. The touch layer 8 is configured to implement a touch function of the display panel, and a touch electrode layer 81 is set on a side of a touch substrate 82.

In step S6.3, the touch layer 8 is connected to the cover plate.

A side of the touch electrode layer 81 away from the touch substrate 82 is connected to the cover plate.

In step S6.4, a third package structure 7 is manufactured.

The third package structure 7 is manufactured on a side of the touch substrate 82 away from the touch electrode layer 81. For example, a transparent indium tin oxide (ITO) layer may be manufactured directly on the side of the touch substrate 82; or a first insulating material may be manufactured on the side of the touch substrate 82, and then a conductive material is added to the first insulating material.

In step S6.5, the third package structure 7 is connected to the second package structure 4.

A side of the third package structure 7 away from the cover plate 82 is connected to a side of the second package structure 4 away from the base substrate 1. Since both the second package structure 4 and the third package structure 7 can be fabricated integrally, when the second package structure 4 is connected to the third package structure 7, the demand of the positioning accuracy is low, so that the fabrication cost of the display panel according to the embodiment of the present disclosure is reduced and the yield thereof is improved.

In summary, a display panel, a display apparatus and a method for manufacturing a display panel are provided in the embodiments of the present disclosure. The light-emitting device is encapsulated by the first package structure of the display panel. The resistivity of the second package structure is lower than that of the first package structure, so that the second package structure has conductivity. The second package structure may be electrically connected to the second semiconductor layer of the light-emitting device and configured to transmit an electrical signal for the light-emitting device, so that a metal electrode electrically connected to the second semiconductor layer can be saved, to simplify a structure and a fabrication technique of the display panel according to the embodiment of the present disclosure, and reducing the fabrication cost thereof. As the second package structure can be integrally fabricated, the demand for processing precision is reduced, the cost is reduced and the yield is improved.

The embodiments described above are only specific embodiments of the present disclosure, while the protection scope of the present disclosure is not limited thereto. Various equivalent modifications or replacements may be made within the scope disclosed in the present disclosure, these modifications or replacements should fall within the protection scope of the present disclosure. Therefore, the protection scope of the present disclosure should be defined by the claims.

What is claimed is:

1. A display panel, comprising:
a base substrate;
a plurality of light-emitting devices located on a side of the base substrate, wherein the light-emitting device comprises a first semiconductor layer, a second semiconductor layer and a light-emitting layer located between the first semiconductor layer and the second semiconductor layer, and the second semiconductor layer is located on a side of the light-emitting layer away from the base substrate;
a first package structure, located on the side of the base substrate, wherein the first package structure comprises a first package part located between two adjacent light-emitting devices of the plurality of light-emitting devices; and
a second package structure, wherein at least part of the second package structure is located on a side of a light-emitting device away from the base substrate, a resistivity of the first package structure is σ1, a resistivity of the second package structure is σ2, and σ2<σ1.

2. The display panel according to claim 1, wherein the second semiconductor layer is in direct contact with the second package structure.

3. The display panel according to claim 2, wherein the second package structure comprises a first part and a second part,
along a direction perpendicular to a plane of the base substrate, the first part overlaps with the light-emitting device and the second part does not overlap with the light-emitting device; and
along the direction perpendicular to the plane of the base substrate, a distance from a surface of the second semiconductor layer away from the base substrate to the base substrate is D1, a distance from a surface of the second part facing the base substrate to the base substrate is D0, and D0<D1.

4. The display panel according to claim 3, wherein, along the direction perpendicular to the plane of the base substrate, a distance from a surface of the second semiconductor layer facing the base substrate to the base substrate is D2, and D0≤D2.

5. The display panel according to claim 1, further comprising:
a display area and a non-display area, wherein at least part of the non-display area surrounds the display area;
a support structure located in the non-display area, wherein the support structure at least partly surrounds the second package structure; and
an array layer, located on the side of the base substrate, wherein the light-emitting device is located on a side of the array layer away from the base substrate, the array layer comprises a first connection located in the non-display area, and a first connection part is located on a side of the support structure closer to the display area,
wherein at least part of the second package structure is in contact connection with the first connection part.

6. The display panel according to claim 5, wherein in the non-display area, the first package structure ends at a first position, and the first position is located on a side of the first connection part closer to the display area.

7. The display panel according to claim 5, wherein the support structure and the first package structure are made of a same material.

8. The display panel according to claim 1, wherein the first package structure comprises a first conductive material, a volume concentration of the first conductive material in the first package structure is P1, the second package structure comprises a second conductive material, a volume concentration of the second conductive material in the second package structure is P2, and P1<P2.

9. The display panel according to claim 8, wherein the first package structure and the second package structure both comprise a first insulating material; and
the first conductive material is the same as the second conductive material.

10. The display panel according to claim 8, wherein the second package structure comprises a first part and a second part,
along a direction perpendicular to a plane of the base substrate, the first part overlaps with the light-emitting device and the second part does not overlap with the light-emitting device; and
a volume concentration of the first conductive material in the first part is P21, a volume concentration of the first conductive material in the second part is P22, and P21≤P22.

11. The display panel according to claim 8, wherein, the light-emitting device comprises a first light-emitting device and a second light-emitting device, a wavelength of light emitted by the first light-emitting device is greater than a wavelength of light emitted by the second light-emitting device;
the second package structure comprises a third part and a fourth part;
on a plane of the base substrate, an orthographic projection of the first light-emitting device is located within an orthographic projection of the third part, and an orthographic projection of the second light-emitting device is located within an orthographic projection of the fourth part; and
a volume concentration of the first conductive material in the third part is P23, a volume concentration of the first conductive material in the fourth part is P24, and P23≥P24.

12. The display panel according to claim 8, further comprising:
a third package structure, wherein at least part of the third package structure is located on a side of the second package structure away from the base substrate, a resistivity of the third package structure is σ3, and σ3<σ2.

13. The display panel according to claim 12, further comprising:
a touch layer, comprising a touch electrode layer and a touch substrate, wherein the touch substrate is located on the side of the second package structure away from the base substrate, and the touch electrode layer is located on a side of the touch substrate away from the base substrate,
wherein the third package structure is located on a side of the touch substrate away from the touch electrode layer, and the third package structure is in contact connection with the touch substrate.

14. The display panel according to claim 1, further comprising:
a display area and a non-display area, wherein at least part of the non-display area surrounds the display area;
a support structure located in the non-display area, wherein the support structure at least partly surrounds the first package structure; and
an array layer located on the side of the base substrate, wherein the light-emitting device is located on a side of the array layer away from the base substrate, the array layer comprises a first connection part located in the non-display area, and the first connection part is located on a side of the support structure closer to the display area.

15. The display panel according to claim 14, wherein in the non-display area, the second package structure ends at a second position, and the second position is located on a side of the first connection part away from the display area.

16. A display apparatus, comprising a display panel,
the display panel comprising:
a base substrate;
a plurality of light-emitting devices located on a side of the base substrate, wherein the light-emitting device comprises a first semiconductor layer, a second semiconductor layer and a light-emitting layer located between the first semiconductor layer and the second semiconductor layer, and the second semiconductor layer is located on a side of the light-emitting layer away from the base substrate;
a first package structure, located on the side of the base substrate, wherein the first package structure comprises a first package part located between two adjacent light-emitting devices; and
a second package structure, wherein at least part of the second package structure is located on a side of the light-emitting device away from the base substrate, a resistivity of the first package structure is σ1, a resistivity of the second package structure is σ2, and σ2<σ1.

17. A method for manufacturing a display panel, the method comprising:
providing a base substrate;
providing a light-emitting device, wherein the light-emitting device comprises a first semiconductor layer, a second semiconductor layer and a light-emitting layer located between the first semiconductor layer and the second semiconductor layer;
connecting the light-emitting device to the base substrate, wherein the second semiconductor layer is located on a side of the light-emitting layer away from the base substrate;
manufacturing a first package structure on a side of the base substrate facing the light-emitting device, wherein the first package structure comprises a first package part located between two adjacent light-emitting devices, and a resistivity of the first package structure is σ1; and
manufacturing a second package structure on a side of the first package structure away from the base substrate, wherein a resistivity of the second package structure is σ2, and σ2<σ1.

18. The method according to claim 17, wherein manufacturing the second package structure on the side of the first package structure away from the base substrate comprises:
manufacturing a first insulating material on the side of the first package structure away from the base substrate, and adding a second conductive material to the first insulating material.

19. The method according to claim 17, further comprising:
providing a cover plate;
manufacturing a third package structure on a side of the cover plate; and
connecting a side of the third package structure away from the cover plate to a side of the second package structure away from the base substrate.

20. The method according to claim 17, further comprising:
providing a cover plate;
providing a touch layer, wherein the touch layer comprises a touch electrode layer and a touch substrate, and the touch electrode layer is located a side of the touch substrate;
connecting a side of the touch electrode layer away from the touch substrate to the cover plate;
manufacturing a third package structure on a side of the touch substrate away from the touch electrode layer; and
connecting a side of the third package structure away from the touch substrate to a side of the second package structure away from the base substrate.
